(19) United States
(12) Patent Application Publication
(10) Pub. No.: US 2026/0255611 A1
(43) Pub. Date: Aug. 27, 2026

(54) OVONIC THRESHOLD SWITCH DEVICES WITH ASYMMETRIC ELECTRODES AND METHODS FOR FORMING THE SAME

(71) Applicant: Sandisk Technologies, Inc., Milpitas, CA (US)

(72) Inventors: Lei WAN, San Jose, CA (US); Michael Nicolas Albert TRAN, San Jose, CA (US); Hans J. RICHTER, Palo Alto, CA (US)

(21) Appl. No.: 19/062,839

(22) Filed: Feb. 25, 2025

(51) Int. Cl. H10B 63/00

(52) U.S. Cl. CPC H10B 63/24

(57) ABSTRACT

An ovonic threshold switch (OTS) element includes a first electrode having a first electrical conductivity, a second electrode having a second electrical conductivity which is higher than the first electrical conductivity, and an OTS material portion located between and directly contacting the first electrode and the second electrode. The OTS element may function as a self-selecting memory (SOM) cell or as a selector element of a memory cell, such as an MRAM memory cell.

### FIELD

The present disclosure is directed generally to the field of semiconductor devices, and particularly to ovonic threshold switch devices with asymmetric electrodes for use in selector-only memory arrays or in series with magnetic tunnel junctions.

### BACKGROUND

A random access memory device is a memory device containing memory cells that allow random access, e.g., access to any selected memory cell upon a command for reading the contents of the selected memory cell. The memory cells of the random access memory device may be arranged in a cross-point configuration, where a bit memory cell resides at every intersection of a bit line and a word line.

### SUMMARY

According to a first embodiment of the present disclosure, an ovonic threshold switch (OTS) memory element includes a first electrode having a first electrical conductivity, a second electrode having a second electrical conductivity which is higher than the first electrical conductivity, and an OTS material portion located between and directly contacting the first electrode and the second electrode.

According a second embodiment of the present disclosure, a memory cell comprises a memory element; and an ovonic threshold switch (OTS) selector electrically connected to the memory element in series. The OTS selector comprises a first electrode having a first electrical conductivity; a second electrode having a second electrical conductivity which is higher than the first electrical conductivity; and an OTS material portion located between and directly contacting the first electrode and the second electrode.

### BRIEF DESCRIPTION OF DRAWINGS

FIG. 1 is a graph illustrating current-voltage characteristics of an ovonic threshold switch device according to an embodiment of the present disclosure.

FIG. 2 is a schematic diagram of a memory device including a two-dimensional array of memory cells of embodiments of the present disclosure in an array configuration.

FIG. 3A is a vertical cross-sectional view of a first comparative exemplary ovonic memory cell structure according to a comparative embodiment of the present disclosure. FIG. 3B is a vertical cross-sectional view of a first exemplary ovonic memory cell structure according to an embodiment of the present disclosure. FIG. 3C is a vertical cross-sectional view of a second exemplary ovonic memory cell structure according to an embodiment of the present disclosure. FIG. 3D is a vertical cross-sectional view of a second comparative exemplary ovonic memory cell structure according to a comparative embodiment of the present disclosure.

FIGS. 4A-4D are vertical cross-sectional views of respective third, fourth, fifth and sixth exemplary ovonic memory cell structures according to alternative embodiments of the present disclosure.

FIGS. 5A-5D are perspective views of alternative embodiment ovonic memory cell structures according to alternative embodiments of the present disclosure.

FIGS. 6A-6D are plots of difference between positive and negative memory window voltages versus critical diameter for the ovonic memory cells of FIGS. 5A-5D, respectively.

FIGS. 7A-7D are vertical cross-sectional views of memory cells containing an OTS selector and an MTJ memory element according to a second embodiment of the present disclosure.

FIGS. 8A-8D are plots of cell current versus time depicting operating steps of the memory cells of FIGS. 7A-7D.

FIGS. 9A-9D are perspective views of memory cells containing an OTS selector and an MTJ memory element of FIGS. 7A-7D, respectively, according to a second embodiment of the present disclosure.

FIGS. 10A-10D are perspective views of alternative memory cells containing an OTS selector and an MTJ memory element of FIGS. 7A-7D, respectively, according to an alternative embodiment of the present disclosure.

### DETAILED DESCRIPTION

As described above, the present disclosure is directed to ovonic threshold switch devices with asymmetric electrodes for use in selector-only memory arrays or in series with magnetic tunnel junctions, the various aspects of which are described below.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a first surface and a second surface are “vertically coincident” with each other if the second surface overlies or underlies the first surface and there exists a vertical plane or a substantially vertical plane that includes the first surface and the second surface. A substantially vertical line is a straight line that deviates from a vertical direction by an angle less than 5 degrees.

Ovonic threshold switch (OTS) devices utilize a threshold switching behavior of an ovonic threshold material. Ovonic threshold materials transition from a high-resistance state to a low-resistance state (i.e., higher and lower resistance states) and vice-versa when a sufficient voltage is applied thereacross. The threshold voltage (Vₜₕ) of an OTS device is a device parameter that determines its switching behavior. Generally, the threshold voltage Vₜₕ of an OTS device can be influenced by the polarity of previously applied voltages employed during a previous turn-on of the OTS device. This phenomenon known as the polarity-dependent memory effect for threshold voltages of an ovonic threshold switch material. The polarity-dependent memory effect results in different threshold voltages depending on whether the immediately preceding turn-on voltage was positive or negative.

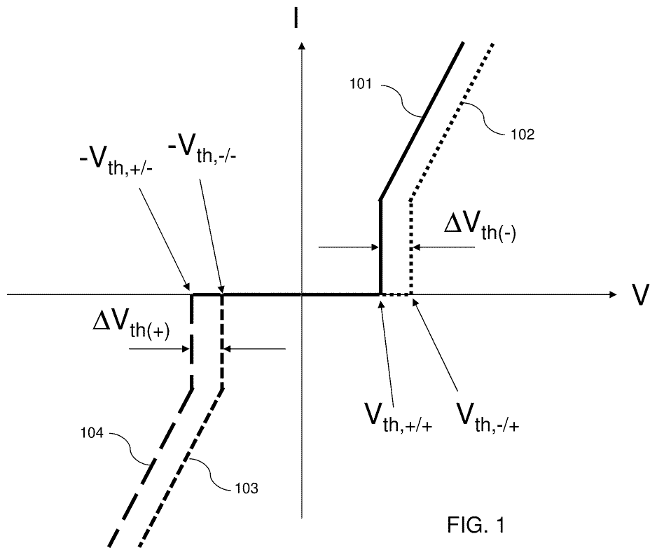

Referring to FIG. 1, current-voltage characteristics of an OTS device are illustrated employing four current-voltage curves (101, 102, 103, 104). The four current-voltage curves (101, 102, 103, 104) in FIG. 1 represent current-voltage characteristics of a same OTS material portion under four different states in which two current pulses of various polarities are applied to the OTS material portion followed by measuring a voltage across the OTS material portion. The first current-voltage curve 101 represents a state where a positive current was applied during the immediately preceding operating step, followed by application of another positive current. The second current-voltage curve 102 represents a state where a negative current was applied during the immediately preceding operating step, followed by an application of a positive current. The third current-voltage curve 103 represents a state where a negative current was applied during the immediately preceding operating step, followed by an application of a negative current. The fourth current-voltage curve 104 represents a state where a positive current was applied during the immediately preceding operating step, followed by an application of a negative current. The polarity-dependent memory effect is demonstrated by the lateral offset of the first current-voltage curve 101 compared to the second current-voltage curve 102 along the positive measured voltage axis, and by the lateral offset of the third current-voltage curve 103 compared to the fourth current-voltage curve 104 along the negative measured voltage axis.

Thus, the threshold voltage for a given voltage polarity depends on the polarity of the previously applied current. Generally, four threshold voltages can be defined for an OTS material portion. For instance, V_{th,+/+} represents the threshold voltage for the state of the first current-voltage curve 101, while V_{th,-/+} represents the threshold voltage for the state of the second current-voltage curve 102. Similarly, V_{th,-/-} represents the threshold voltage for the state of third current-voltage curve 103, while V_{th,+/-} represents the threshold voltage for the state of the fourth current-voltage curve 104. In a majority of cases the absolute value of the threshold voltage after the second programming pulse is higher if the previous first programming pulse had an opposite polarity than the second programming pulse, compared to if the previous first programming pulse had the same polarity as the second programming pulse, as shown in FIG. 1. However, in some cases, when the OTS device width (e.g., diameter) is relatively small (e.g., less than 30 nm), the absolute value of the threshold voltage after the second programming pulse may be lower if the previous first programming pulse had an opposite polarity than the second programming pulse, as shown in FIGS. 6A and 6B (e.g., ΔV_{th (+)} is negative for small device diameters).

The polarity-dependent memory effect described above can be employed to provide an ovonic threshold switch (OTS) memory element. Within such an OTS memory element, the information is stored by the polarity of an immediately preceding programming pulse that was applied to the OTS material portion of the OTS memory element. The OTS memory element stores the information regarding the polarity of the immediately preceding programming pulse in the form of the value of a threshold voltage. Thus, if the immediately preceding programming pulse was positive (i.e., a positive programming current was applied), the OTS material portion exhibits V_{th,+/-} or V_{th,+/+} during a subsequent application of a respective negative or positive programming current pulse. Furthermore, if the immediately preceding programming pulse was negative (i.e., a negative programming current was applied), the OTS material portion exhibits V_{th,-/-} or V_{th,-/+} during a subsequent application of a respective negative or positive programming current pulse.

The difference between two threshold voltages under a given polarity of the second programming current pulse defines the threshold voltage memory window (ΔVₜₕ) for the OTS memory element (i.e., a difference in measured threshold voltages after the application of a second programming current pulse due to a difference in polarity of the first programming current pulse applied prior to the second programming pulse). When the second programming pulse is positive, a negative threshold voltage memory window ΔVₜₕ₍₋₎=V_{th,-/+}−V_{th,+/+} is provided. When the second programming pulse is negative, a positive threshold memory window ΔVₜₕ₍₊₎=V_{th,+/-}−V_{th,-/-} is provided. It should be noted that the negative threshold voltage memory window ΔVₜₕ₍₋₎ may have a negative or a positive value, and the term “negative” in this context refers to the minus sign in the term “ΔVₜₕ₍₋₎” due to the negative polarity of the last voltage pulse applied to a given electrode (e.g., top electrode) of the device before the threshold voltage is measured. Likewise, the term positive threshold voltage memory window ΔVₜₕ₍₊₎ may have a negative or a positive value, and the term “positive” in this context refers to the plus sign in the term “ΔVₜₕ₍₊₎” due to the positive polarity of the last voltage pulse applied to a given electrode (e.g., top electrode) of the device before the threshold voltage is measured. Alternatively, the term “negative threshold voltage memory window ΔVₜₕ₍₋₎” may also be called “threshold voltage memory window where a negative polarity pulse was applied last”, and the term “positive threshold voltage memory window ΔVₜₕ₍₊₎” may also be called “threshold voltage memory window where a positive polarity pulse was applied last.”

Information storage and retrieval in the OTS memory devices may use the polarity-dependent threshold voltage characteristics, such as the differences between the first current-voltage curve 101 and the second current-voltage curve 102, or the differences between the third current-voltage curve 103 and the fourth current-voltage curve 104 (i.e., the positive or negative memory windows). The OTS element may store information based on the polarity of a previously applied programming pulse, which alters the material's structure and shifts its threshold voltage.

In OTS memory devices with symmetric low-conductivity electrodes, a memory window may be as small as 0.1V. This small memory window may limit the ability to reliably differentiate between the memory states of the OTS memory device.

According to an aspect of the present disclosure, the memory window of an OTS memory device can be increased while maintaining device scalability and performance by using different conductivity electrodes on opposite sides of the OTS material portion of the OTS memory device. As will be described in more detail below, asymmetric conductivity electrode configurations in OTS devices may be applied to both OTS selector-only memory devices and to a memory device containing an OTS selector element in series with a memory element (e.g., MRAM MTJ memory element).

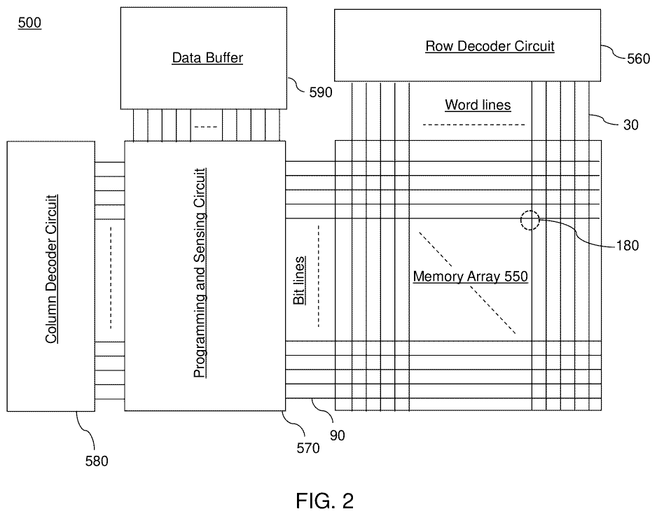

FIG. 2 illustrates a block diagram of a memory device 500. The memory device 500 may include a memory array region 550 containing memory cells 180 arranged in a matrix configuration. The memory array region 550 may be accessed through bottom electrically conductive lines 30 and top electrically conductive lines 90, which may form a crosspoint array structure.

In some embodiments, the memory cells 180 may be implemented as selector-only memory (i.e., self-selecting memory) elements utilizing ovonic threshold switch (OTS) devices. These OTS devices may leverage the polarity-dependent memory effect to store information based on the threshold voltage characteristics. The asymmetric electrode conductivity in these OTS selector-only memory elements may increase the memory window, and may improve the reliability and scalability of high-density memory devices.

In other embodiments, the memory cells 180 may comprise a series connection of an OTS selector and a memory element, such as a magnetoresistive random access memory (MRAM) or phase change memory (PCM) element. The asymmetric electrode configuration in the OTS selector may be selected to minimize the polarity-dependent memory effect.

A first set of electrically conductive lines, which is selected from the set of bottom electrically conductive lines 30 and the set of top electrically conductive lines 90, functions as first electrically conductive lines laterally extending along a first horizontal direction and laterally spaced apart from each other along a second horizontal direction. A second set of electrically conductive lines, which is the complement of the first set of electrically conductive lines, functions as second electrically conductive lines vertically spaced from the first electrically conductive lines, laterally extending along the second horizontal direction, and laterally spaced apart from each other along the first horizontal direction. In one configuration, the first electrically conductive lines function as word lines and the second electrically conductive lines function as bit lines. In an alternative configuration, the first electrically conductive lines function as bit lines and the second electrically conductive lines function as word lines.

If the memory cells 180 comprise selector-only memory elements utilizing ovonic threshold switch (OTS) devices, a two-dimensional array of ovonic threshold switch elements (OTS elements) is located at cross points between the first electrically conductive lines and the second electrically conductive lines. If the memory cells 180 comprise a combination of a respective memory element and a respective OTS selector connected in series, a two-dimensional array of series connections of respective OTS selector and a respective memory element (e.g., magnetic tunnel junction) is located at cross points between the first electrically conductive lines and the second electrically conductive lines.

The memory device 500 may include peripheral circuits for controlling memory operations. A row decoder circuit 560 may be connected to the word lines to provide word line access. A column decoder circuit 580 may be connected to the bit lines to provide bit line access. A programming and sensing circuit 570 may be provided between the column decoder circuit 580 and the top electrically conductive lines 90 for reading data from selected memory cells 180. A data buffer circuit 590 may interface with the programming and sensing circuit 570 for temporarily storing data being read from or written to the memory array region 550. The word lines 30 can be connected to the row decoder circuit 560, and the bit lines 90 can be connected to the programming and sensing circuit 570. The memory cells 180 may be located at intersections of the word lines 30 and the bit lines 90 within the memory array region 550.

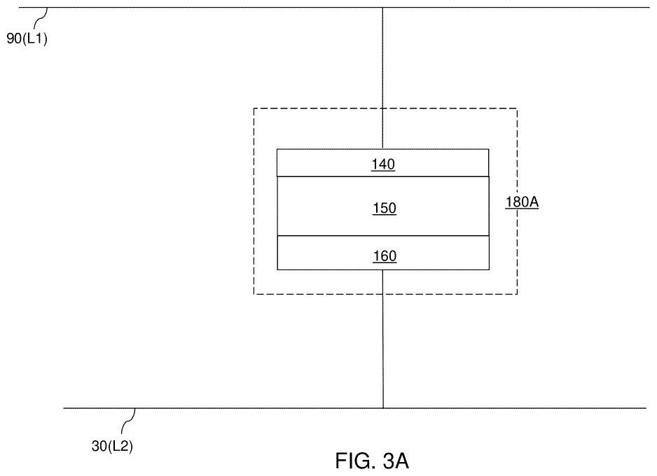

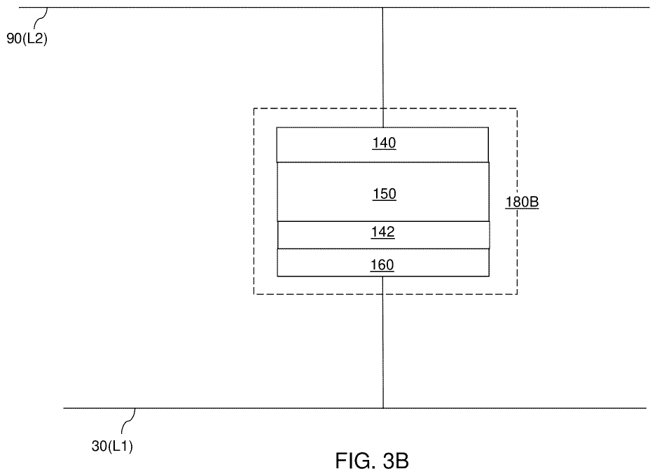

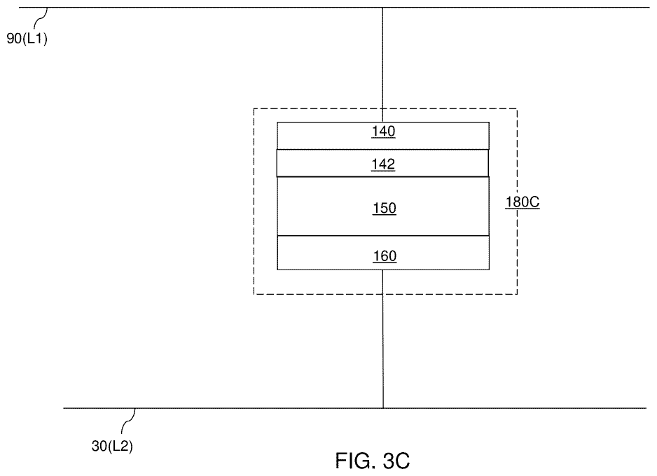

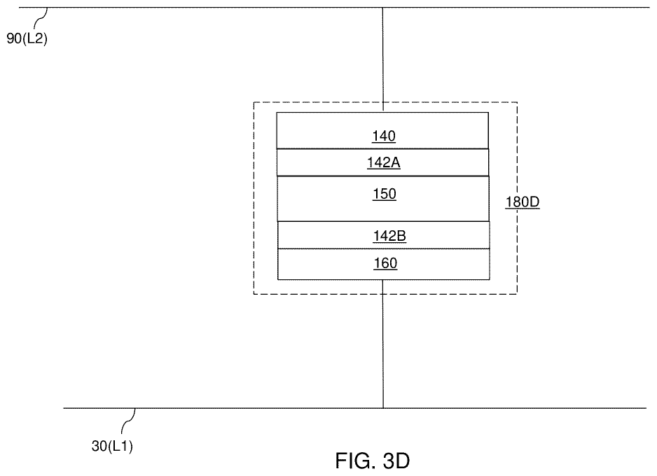

FIGS. 3A and 3D illustrate configurations of an OTS memory device (i.e., the selector-only memory device) according to a comparative example. FIGS. 3B and 3C illustrate configurations of an OTS memory device (i.e., the selector-only memory device) according to examples of a first embodiment of the present disclosure. The OTS memory devices in FIGS. 3A-3D include an OTS memory cell 180 electrically connected to a respective word line 30 and a respective bit line 90.

Referring to FIG. 3A, a first comparative example memory cell 180A may comprise an OTS material portion 150 located between a first electrode 140 and a second electrode 160. In one embodiment, the memory cell 180A may be arranged vertically such that the first electrode 140 comprises an upper electrode that is electrically connected to a first line L1 (e.g., bit line 90), and the second electrode 160 comprises a lower electrode that is electrically connected to a second line L2 (e.g., word line 30). In one embodiment, the memory cell 180 comprises a cylindrical pillar located between the word line 30 and the bit line 90.

The first electrodes 140 and the second electrode 160 may comprise the same electrically conductive material having a relatively low electrical conductivity, such as carbon or carbon nitride. The OTS material portion 150 directly contacts the first electrode 140 and the second electrode 160. The OTS material portion 150 comprises an ovonic threshold switching material which exhibits non-linear electrical behavior. As used herein, an ovonic threshold switching material refers to a material that displays a non-linear resistivity curve under an applied external bias voltage such that the resistivity of the material decreases with the absolute magnitude of the applied external bias voltage greater than the absolute value of the threshold voltage. In one embodiment, the ovonic threshold switch material can comprise a chalcogenide material. The chalcogenide material may be a GeSeAs alloy, a GeSeAsTe alloy, a GeTeAs alloy, a GeSeTe alloy, a GeSe alloy, a SeAs alloy, a AsTe alloy, a GeTe alloy, a SiTe alloy, a SiAsTe alloy, or SiAsSe alloy. The chalcogenide material may be undoped or doped with at least one of N, O, C, P, Ge, As, Te, Se, In, or Si.

Referring to FIG. 3B, a first exemplary memory cell 180B of a first embodiment may be derived from the comparative exemplary memory cell 180A of FIG. 3A by adding a high conductivity, electrically conductive insert 142 between the second electrode 160 and the OTS material portion 150. The electrically conductive insert 142 has a higher conductivity than the first electrode 140 and the second electrode 160, and directly contacts the OTS material portion 150. For example, the insert 142 electrical conductivity is at least 2 times higher, such as 10 to 10,000 times higher than the electrical conductivity of the first and second electrodes. In one embodiment, the insert 142 comprises an electrically conductive metal, metal alloy or a metal nitride which does not damage the OTS material portion 150 due to solid state diffusion. For example, the insert 142 may comprise a refractory metal nitride, such as titanium nitride, tungsten nitride, tantalum nitride or molybdenum nitride.

Referring to FIG. 3C, a second exemplary memory cell 180C of a first embodiment may be derived from the comparative exemplary memory cell 180A of FIG. 3A by adding the high conductivity, electrically conductive insert 142 between the first electrode 140 and the OTS material portion 150. The electrically conductive insert 142 has a higher conductivity than the first electrode 140 and the second electrode 160, and directly contacts the OTS material portion 150.

Referring to FIG. 3D, a second comparative exemplary memory cell 180D of a first embodiment may be derived from the comparative exemplary memory cell 180A of FIG. 3A by adding a first high conductivity, electrically conductive insert 142A between the first electrode 140 and the OTS material portion 150, and a second high conductivity, electrically conductive insert 142B between the second electrode 160 and the OTS material portion 150. The electrically conductive inserts 142A and 142B have a higher conductivity than the first electrode 140 and the second electrode 160, and directly contact the OTS material portion 150.

Table 1 below illustrates measured ΔVₜₕ₍₊₎ and ΔVₜₕ₍₋₎ values for three batches of memory cells 180A, 180B, 180C and 180D across ten wafers, having the structures described above.

TABLE 1

| | | Cell 180A | Cell 180B | Cell 180C | Cell 180D |
|---|---|---|---|---|---|
| Batch # | ΔVₜₕ | of FIG. 3A | of FIG. 3B | of FIG. 3C | of FIG. 3D |
| Batch #1 | ΔVₜₕ₍₊₎ | ~0.13 V | ~0.05 V | ~0.35 V | ~0.3 V |
| | ΔVₜₕ₍₋₎ | ~0.27 V | ~0.35 V | ~0.17 V | ~0.3 V |
| Batch #2 | ΔVₜₕ₍₊₎ | ~0.15 V | N/A | ~0.4 V | ~0.3 V |
| | ΔVₜₕ₍₋₎ | ~0.3 V | N/A | ~0.2 V | ~0.3 V |
| Batch #3 | ΔVₜₕ₍₊₎ | ~0.1 V | 0 V | ~0.22 V | N/A |
| | ΔVₜₕ₍₋₎ | ~0.2 V | ~0.3 V | ~0.1 V | N/A |

For comparative example memory cells 180A with symmetric low-conductivity electrodes (140, 160) placed above and below the OTS material portion 150, ΔVₜₕ₍₋₎ was ~0.1V larger than ΔVₜₕ₍₊₎. In contrast, a notable greater difference between ΔVₜₕ₍₊₎ and ΔVₜₕ₍₋₎ was determined for exemplary memory cells with asymmetric electrodes: ΔVₜₕ₍₋₎>ΔVₜₕ₍₊₎ by about 0.3V for exemplary memory cells 180B where the high-conductivity insert 142 was placed below OTS material portion 150, and ΔVₜₕ₍₊₎>ΔVₜₕ₍₋₎ by about 0.2V for exemplary memory cells 180C where the high-conductivity insert 142 was located above the OTS material portion 150. For comparative exemplary memory cells 180D with high-conductivity inserts 142A and 142B located above and below OTS material portion 150, nearly identical ΔVₜₕ₍₊₎ and ΔVₜₕ₍₋₎ values were determined.

Overall, by introducing asymmetry in electrode types, a strong polarity dependance (in case either negative or positive voltage applied on top electrode 140 before measurements) was observed in memory window and higher ΔVₜₕ values were achieved.

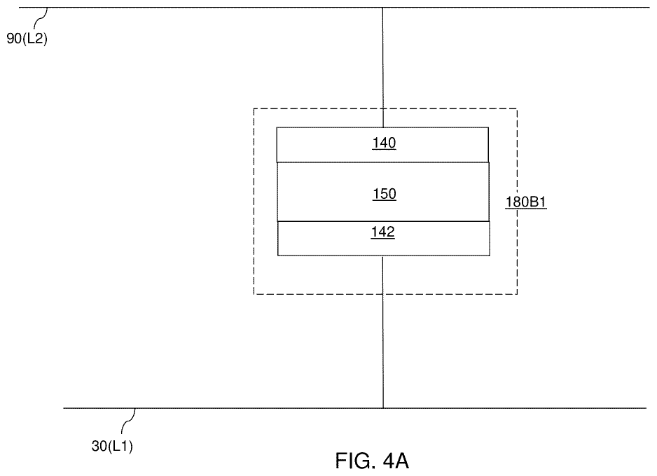

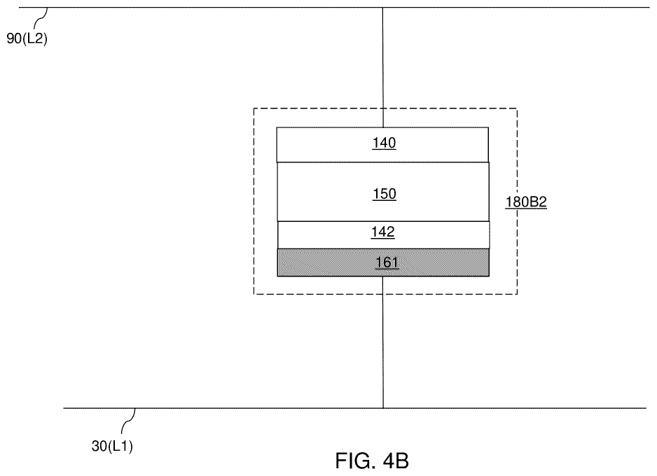

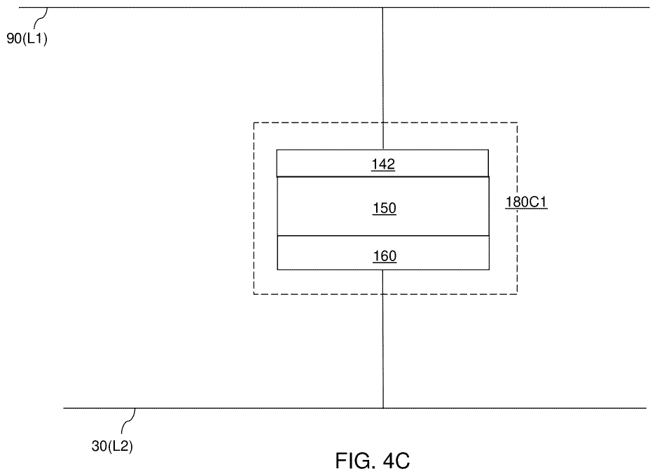

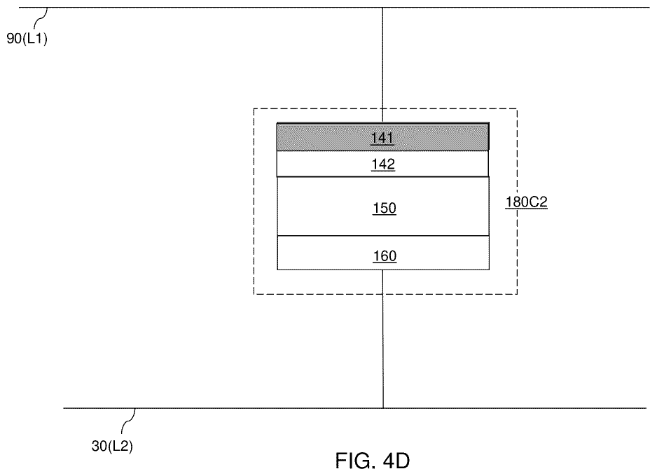

FIG. 4A illustrates a first alternative exemplary memory cell 180B1. The memory cell 180B1 may be derived from the exemplary memory cell 180B by replacing the combination of the insert 142 and the second electrode 160 with the insert 142. In other words, the low conductivity electrode 160 is omitted, and the insert 142 acts as the lower electrode of the memory cell 180B1.

FIG. 4B illustrates a second alternative exemplary memory cell 180B2. The memory cell 180B2 may be derived from the exemplary memory cell 180B by replacing the low conductivity second electrode 160 with a high conductivity second electrode 161. In this cell 180B2, the insert 142 may comprise a refractory metal nitride, such as titanium nitride, while the second electrode 161 comprises a metal or metal alloy, such as tungsten, ruthenium, molybdenum, etc., which may optionally have a higher conductivity than the insert 142.

FIG. 4C illustrates a third alternative exemplary memory cell 180C1. The memory cell 180C1 may be derived from the exemplary memory cell 180C by replacing the combination of the insert 142 and the first electrode 140 with the insert 142. In other words, the low conductivity electrode 140 is omitted, and the insert 142 acts as the upper electrode of the memory cell 180C1.

FIG. 4D illustrates a fourth alternative exemplary memory cell 180C2. The memory cell 180C2 may be derived from the exemplary memory cell 180C by replacing the low conductivity first electrode 140 with a high conductivity second electrode 141. In this cell 180C2, the insert 142 may comprise a refractory metal nitride, such as titanium nitride, while the first electrode 141 comprises a metal or metal alloy, such as tungsten, ruthenium, molybdenum, etc., which may optionally have a higher conductivity than the insert 142.

As described above, the lower conductivity first and second electrodes (140, 160) may comprise carbon or carbon nitride. Carbon may comprise graphite, diamond like carbon, amorphous carbon. For instance, graphite may have an approximate conductivity of 1.0×10⁵ S/m, which may be lower than typical metal nitrides. Diamond-like carbon (DLC), may provide a range of electrical conductivities. Depending on the specific form and processing conditions, the electrical conductivity of DLC may range from approximately 1.0×10⁴ S/m to 3.0×10⁵ S/m, which may be lower than typical transition metal nitrides. Amorphous carbon, may provide even lower conductivities, potentially ranging from about 1 S/m to 10⁵ S/m, depending on the specific form and processing conditions. Carbon nitride may be utilized when very low conductivities are desired. Carbon nitride often behaves more like a wide-bandgap semiconductor, with typical conductivities below 10² S/m, which may be significantly lower than metal nitrides of the insert 142.

In contrast, the insert 142 may comprise a refractory metal nitride material. For example, titanium nitride (TiN) has electrical conductivity ranging from 1.7×10⁶ S/m to 5.0×10⁶ S/m. Tantalum nitride (TaN) has electrical conductivity in a range from 3.3×10⁵ S/m to 2.0×10⁶ S/m. Tungsten nitride (WN) has electrical conductivity in a range from 2.5×10⁵ S/m to 1.25×10⁶ S/m. Molybdenum nitride (MoN) has electrical conductivity in a range from 5.0×10⁵ S/m to 2.0×10⁶ S/m.

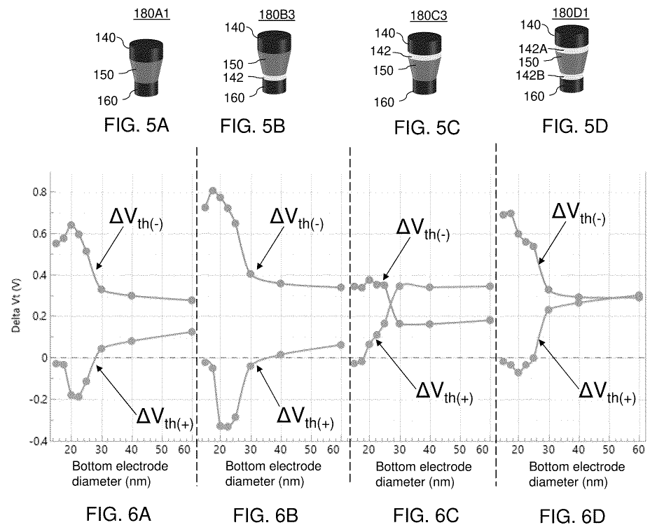

FIGS. 5A-5D illustrate four alternative embodiment OTS memory cells 180A1, 180B3, 180C3 and 180D1 which are derived from respective comparative and exemplary OTS memory cells 180A, 180B, 180C and 180D of FIGS. 3A-3D, respectively. Each of the alternative embodiment OTS memory cells comprises a tapered cylindrical memory cell in which the first (e.g., upper) electrode 140 has a larger width (e.g., diameter) than the lower electrode 160. The respective OTS material portion 150 of the alternative embodiment OTS memory cells 180A1, 180B3, 180C3 and 180D1 have a shape of a conical frustum. The conical frustums are aligned along a vertical direction such that the horizontal cross-sectional shape of the conical frustum increases along an upward vertical direction.

The four configurations for the alternative OTS memory cells 180A1, 180B3, 180C3 and 180D1 of FIGS. 5A-5D demonstrate the effect of interaction between different diameter and conductivity of the upper and lower electrodes as well as the frustum shape of the OTS material portion 150.

FIGS. 6A-6D illustrate negative and positive median threshold voltage difference values (ΔVₜₕ₍₋₎, ΔVₜₕ₍₊₎) as a function of bottom electrode diameter for OTS memory cells 180A1, 180B3, 180C3 and 180D1 of FIGS. 5A-5D, respectively.

As shown in FIGS. 6A-6D, reduction in the size of the lower electrode 160 relative to size the upper electrode 140 increased the absolute value of both the negative and positive median threshold voltage difference values (ΔVₜₕ₍₋₎, ΔVₜₕ₍₊₎). Thus, the increase in OTS memory cell size anisotropy increases the memory window of the memory cells. Furthermore, the memory window is polarity dependent (i.e., applying positive or negative voltage on the top electrode 140). ΔVₜₕ₍₋₎ value is obtained when a negative programming pulse is applied to the top electrode 140, while ΔV_{th (+)} is obtained when a positive programming pulse is applied to the top electrode 140 before the threshold voltage difference is measured.

The alternative embodiment OTS memory cell 180B3 of FIG. 5B in which the high conductivity insert 142 is located between smaller diameter bottom end of the OTS material portion 150 and the smaller diameter bottom electrode 160 provides a larger difference between the ΔVₜₕ₍₋₎ and ΔVₜₕ₍₊₎ values than the other alternative embodiment memory cells 180A, 180C3, 180D1. Thus, the shape anisotropy and the electrode conductivity difference provide a synergistic benefit in increasing the memory window for a selector-only memory (SOM) type device. Specifically, when the high-conductivity insert 142 is located below the narrow bottom end of the OTS material portion 150, the polarity dependence for the asymmetry in electrode conductivity is the same as that for shape anisotropy (i.e., frustum shape of the cell). Therefore, these two effects can synergistically improve the memory window for a self-selecting OTS memory device (i.e., for a SOM type memory device). As shown in FIG. 5B, the ΔVₜₕ₍₋₎ values are higher at all critical diameters than those in FIG. 5A, while the ΔVₜₕ₍₊₎ values are lower at all critical diameter values than those shown in FIG. 5A. For example, for critical diameter values between 20 and 30 nm, the difference between ΔVₜₕ₍₋₎ and ΔV_{th (+)} is greater than 0.5V (e.g., at least 0.6V, such as 0.6-0.7V).

In contrast, in the cell 180C3 of FIG. 5C, the high conductivity insert 142 is located above the wide top end of the OTS material portion 150, and the polarity dependence for the asymmetry in electrode conductivity type is opposite to that for shape anisotropy. Therefore, these two effects offset each other, and decrease the absolute value of ΔVₜₕ₍₊₎, such that this value equals to or is close to zero for relatively small critical diameters of the device (e.g., between 15 and 20 nm). Thus, the cell 180C3 is more suitable for use as a selector element located in series with a bottom pinned MTJ memory element of a MRAM memory cell, as will be explained in more detail below.

In summary, an ovonic threshold switch (OTS) memory element 180 of the first embodiment includes a first electrode having a first electrical conductivity, a second electrode having a second electrical conductivity which is higher than the first electrical conductivity, and an OTS material portion 150 located between and directly contacting the first electrode and the second electrode. In various embodiments, the second electrical conductivity is at least two times higher, such as at least ten times higher, than the first electrical conductivity. The OTS memory element 180 of the first embodiment functions as a selector-only memory device without a separate memory element located in series with the OTS memory element 180.

In one embodiment, the selector-only memory device is operated as follows. A negative or positive read polarity is selected for the device. If a negative read polarity is selected, then the device is designed to maximize the absolute value of ΔVₜₕ₍₊₎. If a positive read polarity is selected, then the device is designed to maximize the absolute value of ΔVₜₕ₍₋₎. In an alternative embodiment, the values of ΔVₜₕ₍₋₎ and ΔVₜₕ₍₊₎ for the device are determined. The read polarity is then selected depending on which absolute value of ΔVₜₕ₍₋₎ and ΔV_{th (+)} is greater. Thus, if the absolute value of ΔVₜₕ₍₋₎ is greater than the absolute value of ΔVₜₕ₍₊₎, then a positive read polarity is used during operation of the device. In contrast, if the absolute value of ΔV_{th (+)} is greater than the absolute value of ΔVₜₕ₍₋₎, then a negative read polarity is used during operation of the device.

In one embodiment, the OTS memory element 180 comprises a vertical stack of the first electrode, the OTS material portion 150 and the second electrode. In the embodiment illustrated in FIGS. 3B, 4A, 4B and 5B, the first electrode 140 is located above the OTS material portion 150 and the second electrode {142, (142, 160), (142, 161)} is located below the OTS material portion 150. In another embodiment illustrated in FIGS. 3C, 4C, 4D and 5C, the first electrode 160 is located below the OTS material portion 150 and the second electrode {142, (142, 140), (142, 141)} is located above the OTS material portion 150.

In one embodiment illustrated in FIGS. 3B and 3C, the second electrode comprises an outer portion (140 or 160) and an insert 142 having the second electrical conductivity which is located between the outer portion (140 or 160) and the OTS material portion 150, and the insert 142 directly contacts the OTS material portion 150. The first electrode (140 or 160) may consist essentially of carbon or carbon nitride material having the first electrical conductivity and directly contacting the OTS material portion 150, the outer portion (160 or 140) of the second electrode may consist essentially of the carbon or carbon nitride material, and the insert may comprise 142 a conductive metal nitride material. For example, the insert 142 may comprise TiN, TaN, WN or MON, and the OTS material portion 150 may comprise an amorphous chalcogenide material.

In another embodiment illustrated in FIGS. 4A-4D, the first electrode (140 or 160) comprises a carbon or carbon nitride material directly contacting the OTS material portion, and the second electrode 142 comprises a metal, metal alloy or a conductive metal nitride material directly contacting the OTS material portion 150.

In the embodiments of FIGS. 3B, 3C and 4A-4D the OTS memory element 180 has a cylindrical shape in which a sidewall of the OTS material portion 150 is vertically coincident with a respective sidewall of the first electrode and is vertically coincident with a respective sidewall of the second electrode. In other words, the OTS memory element has a cylindrical shape with a straight vertical sidewall.

In the alternative embodiment of FIG. 5B, the OTS memory element 150 has a tapered shape. In this embodiment, the OTS material portion 150 comprises a tapered sidewall having a uniform taper angle between 5 and 45 agrees relative to a vertical direction. Furthermore, first electrode 140 has a first horizontal cross-sectional area, and the second electrode (142, 160) has a second horizontal cross-sectional area which is smaller (e.g., at least 50% smaller, such as 2 to 10 times smaller) than the first horizontal cross-sectional area, the first electrode 140 is located above the OTS material portion 150 and the second electrode (142, 160) is located below the OTS material portion 150.

In the embodiment of FIG. 2, an ovonic memory device (i.e., an ovonic memory array) 500 comprises first electrically conductive lines 30 laterally extending along a first horizontal direction and laterally spaced apart from each other along a second horizontal direction; second electrically conductive lines 90 vertically spaced from the first electrically conductive lines 30, laterally extending along the second horizontal direction, and laterally spaced apart from each other along the first horizontal direction; and a two-dimensional array of the OTS memory elements 180 located at cross points between the first electrically conductive lines 30 and the second electrically conductive lines 90. The ovonic memory device 500 also includes a programming and sensing circuit 570 electrically connected to one of the first and second electrically conductive lines, and a row decoder circuit 560 electrically connected to another one of the first and second electrically conductive lines.

In a second embodiment, the OTS element described above functions as a selector 200 of a memory cell 180. The selector 200 is electrically connected in series to a memory element 210 in the memory cell. The memory element 210 may comprise any suitable memory element, such as a MRAM memory element (e.g., a magnetic tunnel junction), a PCM memory element, a resistive memory element, etc. The PCM memory element may comprise a chalcogenide material which switches from a crystalline to an amorphous phase and vice-versa upon application of programming pulses to store a data bit, while the OTS selector 200 remains in the amorphous state. The resistive memory element may comprise a metal oxide layer which switches its resistivity (e.g., by formation of conductive filaments and/or vacancy diffusion therein) upon application of programming pulses to store a data bit. The MRAM memory element may comprise a spin transfer torque (STT) MRAM memory element or another suitable MRAM memory element. The MRAM memory element 210 will be described in more detail below.

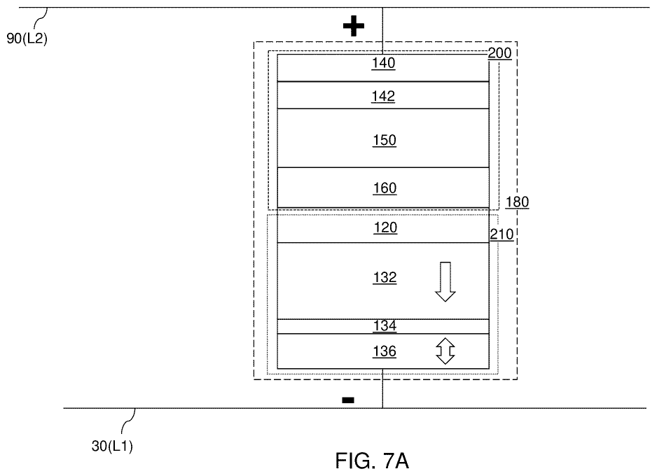

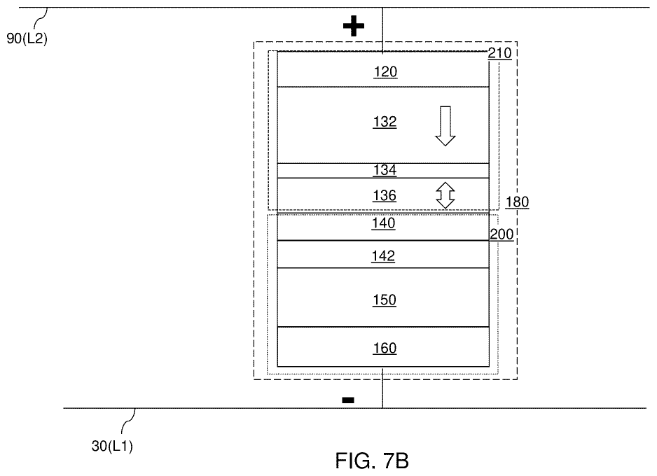

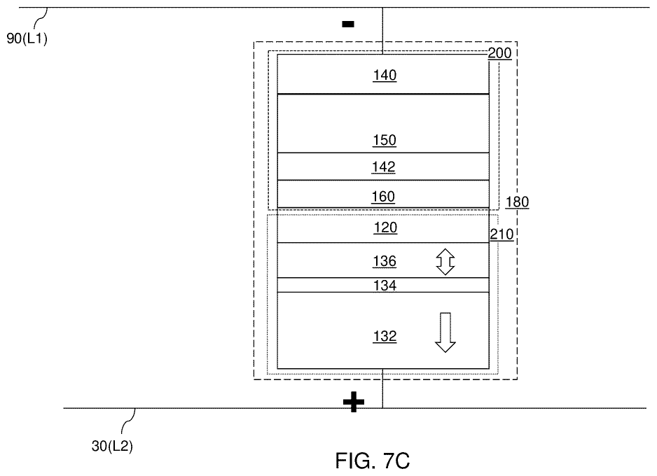

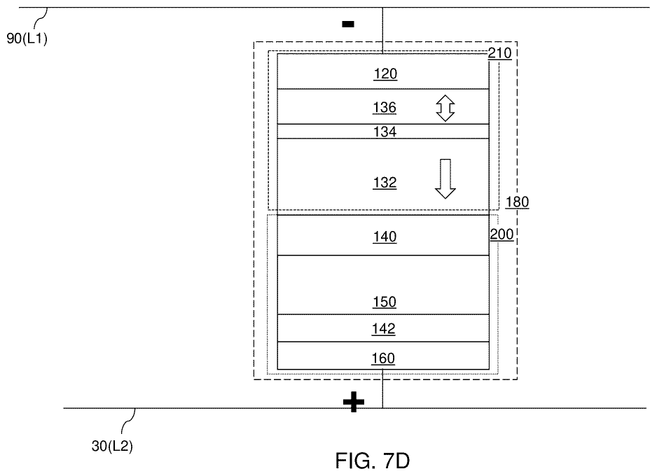

Referring to FIGS. 7A-7D, various configurations of memory cells 180 are illustrated. Each memory cell 180 includes a series connections of an OTS selector 200 and a magnetic tunnel junction (MTJ) memory element 210. While the OTS selector 200 containing the insert 142 of FIGS. 3B and 3C is illustrated in FIGS. 7A-7D, in alternative embodiments, the OTS selector 200 having structure shown in FIG. 4A-4D or 5C may be used instead. Thus, the OTS selector 200 includes elements 140, 142, 150 and 160 described above. The OTS selector 200 may have a cylindrical shape with a straight sidewall or a tapered shape (e.g., such as shown in FIG. 5C), where the larger diameter electrode has a higher conductivity than the smaller diameter electrode, as described above.

The MTJ memory element 210 includes a reference layer 132, a tunneling barrier layer 134 and a free layer 136. The tunneling dielectric layer 134 may comprise an electrically insulating material such as magnesium oxide (MgO), having a thickness in a range from 0.7 nm to 2.4 nm, although lesser and greater thickness may also be employed. The free layer 136 and the reference layer 132 may comprise a ferromagnetic material, such as CoFeB, NiFe, CoFe, Co, Ni, or a combination thereof. The thickness of the free layer 136 may be in a range from 1 nm to 3 nm, although lesser and greater thicknesses may also be employed. The thickness of the reference layer 132 may be in a range from 2.5 nm to 10 nm, although lesser and greater thicknesses may also be employed. The reference layer 132 may also include a polarizer (i.e., pinning) structure (not shown for clarity) which functions as a hard magnetization layer having a stable magnetization direction. The polarizer structure may comprise a ferromagnetic multilayer structure including a superlattice, an exchange-bias-inducing antiferromagnetic layer, or a stack of at least one ferromagnetic material layer and at least one antiferromagnetic layer. Alternatively, the polarizer structure may comprise a synthetic antiferromagnetic (SAF) structure. Generally, the polarizer structure may comprise any magnetic structure that can pin the magnetization direction of the reference layer 132.

In FIGS. 7A-7D, the side with a relative positive voltage during a sensing operation is marked with the symbol “+.” and the side which is at a relative negative voltage during the sensing operation is marked with the symbol “-.”

In the second embodiment, the memory cell 180 containing the MTJ memory element 210 is read with the same polarity as the write polarity that switches the MTJ memory element to the antiparallel state (i.e., the RESET state where the magnetization direction of the free layer 136 is antiparallel to the magnetization direction of the reference layer 132). Thus, for bottom pinned MTJ memory elements, the memory cell 180 is read with a negative polarity, and the OTS selector 200 is designed to minimize its ΔVₜₕ₍₊₎ (to minimize snapback disturb on the MTJ memory element 210) and to maximize its ΔVₜₕ₍₋₎ (so that the additional snapback assists in SET programming operation, switching the MTJ memory element to the parallel state where the magnetization direction of the free layer 136 is parallel to the magnetization direction of the reference layer 132). In contrast, for a top pinned MTJ memory element 210, the memory cell 180 is read with a positive polarity, and the OTS selector 200 is designed to minimize its ΔVₜₕ₍₋₎ (to minimize snapback disturb on the MTJ memory element 210) and maximize its ΔVₜₕ₍₊₎ (so that the additional snapback assists in SET programming operation, switching the MTJ memory element to the parallel state where the magnetization direction of the free layer 136 is parallel to the magnetization direction of the reference layer 132).

Referring to FIG. 7A, a memory cell 180 including a first exemplary magnetic tunnel junction memory element 210 structure is illustrated. In this embodiment, the MTJ memory element 210 is located below the OTS selector 200, and the MTJ memory element 210 is top pinned because the reference layer 132 is located above the free layer 136. Thus, the read current flows from the top to the bottom (i.e., from the reference layer to the free layer) of the memory cell 180 such that the sensed voltage at the top of the memory cell is more positive than the sensed voltage at the bottom of the memory cell. Thus, a positive read voltage is preferably sensed at the reference layer 132 side of the memory cell 180 and a negative read voltage is preferably sensed at the free layer 136 side of the memory cell 180.

Each memory cell 180 is located between bottom electrically conductive lines 30 and top electrically conductive lines 90. The memory cell 180 may comprise a vertical stack including, from bottom to top, a ferromagnetic free layer 136, a tunneling barrier layer 134, a ferromagnetic reference (i.e., pinned) layer 132, a connection electrode 120, the bottom electrode 160, the OTS material portion 150, the insert 142, and a bottom electrode 160. In this configuration, the free layer 136 can be in electrical contact with the first electrically conductive line L1 (i.e., the bottom electrically conductive line 30), and the reference layer 132 may be more proximal to the OTS material portion 150 than the free layer 136 is to the OTS material portion 150.

Referring to FIG. 7B, a memory cell 180 including a second exemplary magnetic tunnel junction memory element 210 structure is illustrated. The memory cell 180 of FIG. 7B can be derived from the structure illustrated in FIG. 7A by exchanging the positions between the OTS selector 200 and the magnetic tunnel junction (132, 134, 136) memory element 210. In this embodiment, the memory element 210 is also a top pinned MTJ, but which is located above (instead of below) the OTS selector 200. A positive read voltage is preferably sensed at the reference layer 132 side of the memory cell 180 and a negative read voltage is preferably sensed at the free layer 136 side of the memory cell 180.

The connection electrode 120 in the memory cells 180 of FIGS. 7A and 7B may be omitted, or additional connection electrodes (not illustrated) may be inserted outside of the magnetic tunnel junction (132, 134, 136) memory element 210 and outside the OTS selector 200 to improve the device performance.

Referring to FIGS. 7A and 7B, the magnetic tunnel junction (132, 134, 136) memory element 210 can be programmed into a low resistance (i.e., SET) state, which is a parallel magnetization state in which the magnetization direction of the free layer 136 becomes parallel to the magnetization direction of the reference layer 132, by inducing an electrical current in which electrons move through the tunneling barrier layer 134 from the reference layer 132 toward the free layer 136. When the electrons move from the reference layer 132 toward the free layer 136, electrical current as defined by the flow direction of hypothetical positive charges flows from the free layer 136 toward the reference layer 132. The magnetic tunnel junction (132, 134, 136) can be programmed into a high resistance (i.e., RESET) state, which is an antiparallel magnetization state in which the magnetization direction of the free layer 136 becomes antiparallel to the magnetization direction of the reference layer 132, by inducing an electrical current in which electrons move through the tunneling barrier layer 134 from the free layer 136 toward the reference layer 132, and the electrical current as defined by the flow direction of hypothetical positive charges flows from the reference layer 132 toward the free layer 136.

The resistive state of the memory element 210 is sensed (i.e., read) by applying a low read current across the memory cell 180 that is sufficient to turn on the OTS selector element 200 and is insufficient to program the magnetic tunnel junction (132, 134, 136) memory element 210 (i.e., to change the parallel to the antiparallel magnetization step or vice-versa). The read current is applied in the RESET direction such that the cell current flows from the reference layer 132 to the free layer 136 (i.e., top to bottom in the cell 180 of FIGS. 7A and 7B).

For a top pinned MTJ memory element 210 of the memory cells 180 of FIGS. 7A and 7B, a positive read voltage and a positive RESET voltage are sensed at the top of the memory cells 180 during sensing and RESET programming steps, and a negative SET voltage is present at the top of the memory cells 180 during a SET programming step.

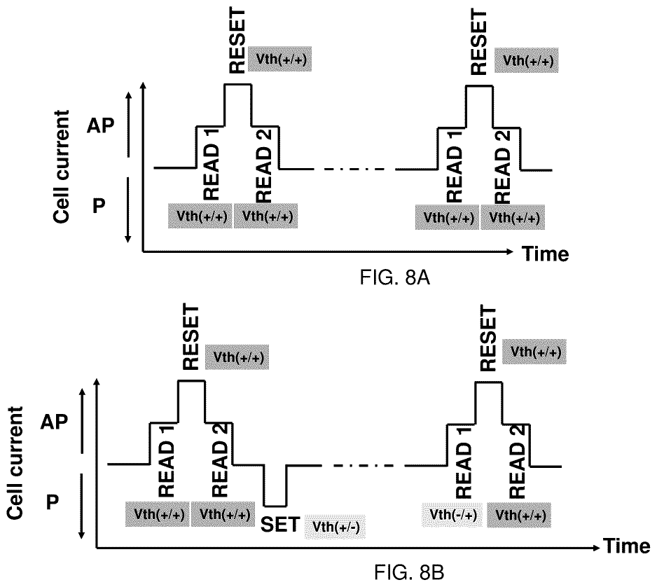

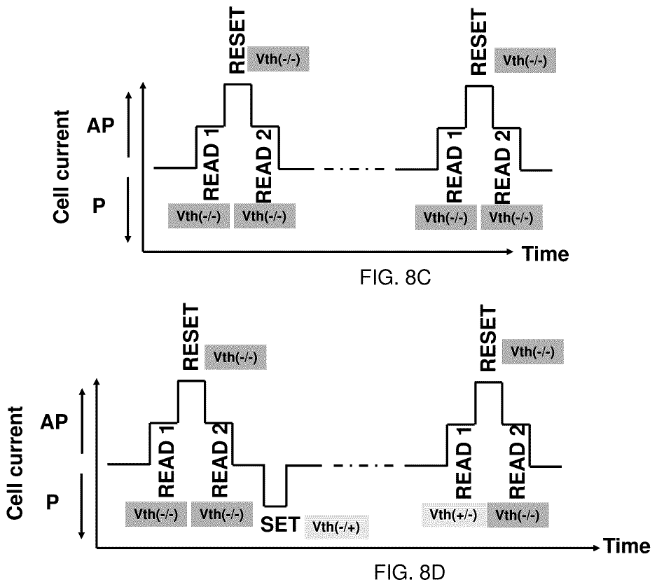

In one embodiment shown in FIGS. 8A and 8B, the resistive state of the MTJ memory element 210 of FIGS. 7A and 7B is sensed by applying two low read current pulses in the RESET direction separated by a high RESET programming current pulse, and then measuring and comparing the two sensed read voltages. If the two read voltages are the same, then the memory element 210 was in the high resistivity, antiparallel RESET state. If the two read voltages are different from each other, then the memory element 210 was in the low resistivity, parallel SET state.

For example, as shown in FIG. 8A, the memory element 210 is first programmed into the high resistivity, antiparallel RESET state by applying two low read current pulses separated by a high current RESET pulse in the RESET direction. The threshold voltage of the memory cell 180 has the V_{th,+/+} value described above. The memory cell 180 is then read by applying the two low read current pulses separated by a high current RESET pulse in the RESET direction. The sensed read voltage of the memory cell 180 has the V_{th,+/+} value during the first read current pulse and during the second read current pulse. Since the sensed read voltage during the first and the second read pulses is the same, the sensing operation determines that the memory element 210 was in the antiparallel RESET state prior to the read operation.

In contrast, as shown in FIG. 8B, the memory element 210 is first programmed into the high resistivity, antiparallel RESET state by applying two low read current pulses separated by a high current RESET pulse in the RESET direction. The threshold voltage of the memory cell 180 has the V_{th,+/+} value. The memory element 210 is then programmed into the low resistivity, parallel SET state by applying a high current SET pulse in the SET direction. The threshold voltage of the memory cell 180 switches from V_{th,+/+} value to the V_{th,+/-} value. It is desirable to maximize the V_{th,+/-} value to enhance the write probability to the SET state. The memory cell 180 is then read by applying the two low read current pulses separated by a high current RESET pulse in the RESET direction. The threshold voltage of the memory cell 180 switches from the V_{th,+/-} value to the V_{th,-/+} value after the first read current pulse. It is desirable to minimize the V_{th,-/+} value to avoid read disturb during the sensing (i.e., reading operation). The memory cell 180 switches to the V_{th,+/+} value after the high current RESET pulse and remains in the V_{th, +/+} value after the second low current read pulse. Since the sensed read voltages during the first and the second read pulses are different, the sensing operation determines that the memory element 210 was in the parallel SET state prior to the read operation.

In order to maximize the V_{th,+/-} value and to minimize the V_{th,+/-} value in a top pinned MTJ memory cell 180 (to which a positive read voltage is applied to the top), the ΔVₜₕ₍₊₎ value should be maximized, and the ΔVₜₕ₍₋₎ value should be minimized. Therefore, the high conductivity insert (or the high conductivity electrode) 142 is located on top of the OTS memory material portion 150 of the OTS selector 200 to maximize ΔVₜₕ₍₊₎ and minimize ΔVₜₕ₍₋₎.

Referring to FIG. 7C, a memory cell 180 including the third exemplary magnetic tunnel junction memory element 210 structure is illustrated. In this embodiment, the MTJ memory element 210 is located below the OTS selector 200, similar to the configuration shown in FIG. 7A. However, in this embodiment, the MTJ memory element 210 is bottom pinned because the reference layer 132 is located below the free layer 136. Thus, the read current flows from the bottom to the top (i.e., from the reference layer to the free layer) of the memory cell 180 such that the voltage at the top of the memory cell is more negative than the voltage at the bottom of the memory cell. A positive read voltage is preferably sensed at the reference layer 132 side of the memory cell 180 and a negative read voltage is sensed at the free layer 136 side of the memory cell 180.

Each memory cell 180 is located between bottom electrically conductive lines 30 and top electrically conductive lines 90. The memory cell 180 may comprise a vertical stack including, from bottom to top, a ferromagnetic reference (i.e., pinned) layer 132, a tunneling barrier layer 134, a ferromagnetic free layer 136, a connection electrode 120, the bottom electrode 160, the OTS material portion 150, the insert 142 and the top electrode 140. In this configuration, the reference layer 132 can be in electrical contact with the first electrically conductive line L1 (i.e., the bottom electrically conductive line 30), and the free layer 136 may be more proximal to the OTS material portion 150 than the reference layer 132 is to the OTS material portion 150.

Referring to FIG. 7D, a memory cell 180 including a fourth exemplary magnetic tunnel junction memory element 210 structure is illustrated. The memory cell 180 of FIG. 7D can be derived from the structure illustrated in FIG. 7C by exchanging the positions between the OTS selector 200 and the magnetic tunnel junction (132, 134, 136) memory element 210. In this embodiment, the memory element 210 is also a bottom pinned MTJ, but which is located above (instead of below) the OTS selector 200. A positive read voltage is preferably sensed at the reference layer 132 side of the memory cell 180 and a negative read voltage is preferably sensed at the free layer 136 side of the memory cell 180.

The connection electrode 120 in the memory cells 180 of FIGS. 7C and 7D may be omitted, or additional connection electrodes (not illustrated) may be inserted outside of the magnetic tunnel junction (132, 134, 136) memory element 210 and outside the OTS selector 200 to improve the device performance.

Referring to FIGS. 7C and 7D, the bottom pinned magnetic tunnel junction (132, 134, 136) memory element 210 can be sensed and programmed in the same manner as in the top pinned memory element 210 of FIGS. 7A and 7B, except that the voltage polarity provided to the top and bottom of the memory cells 180 is reversed. Therefore, the read current, RESET programming current and the SET programming current flow in opposite direction in the memory cells 180 of FIGS. 7C and 7D relative to the direction in the memory cells 180 of FIGS. 7A and 7B. Thus, for the bottom pinned MTJ memory element 210 of the memory cells 180 of FIGS. 7C and 7D, a negative read voltage and a positive RESET voltage are provided to the top of the memory cells 180 during sensing and RESET programming steps, and a positive SET voltage is provided to the top of the memory cells 180 during a SET programming step.

In another embodiment shown in FIGS. 8C and 8D, the resistive state of the bottom pinned MTJ memory element 210 of FIGS. 7C and 7D is sensed by applying two low read current pulses in the RESET direction separated by a high RESET programming current pulse, and then measuring and comparing the two read voltages sensed during the read current pulses. If the two read voltages are the same, then the memory element 210 was in the high resistivity, antiparallel RESET state. If the two read voltages are different from each other, then the memory element 210 was in the low resistivity, parallel SET state.

For example, as shown in FIG. 8C, the memory element 210 is first programmed into the high resistivity, antiparallel RESET state by applying two low read current pulses separated by a high current RESET pulse in the RESET direction. The threshold voltage of the memory cell 180 has the V_{th,-/-} value described above. The memory cell 180 is then read by applying the two low read current pulses separated by a high current RESET pulse in the RESET direction. The threshold voltage of the memory cell 180 has the V_{th,-/-} value after the first read current pulse, after the high current RESET pulse and after the second low current read pulse. Since the first and second read voltages sensed during the first and the second read pulses are the same, the sensing operation determines that the memory element 210 was in the antiparallel RESET state prior to the read operation.

In contrast, as shown in FIG. 8D, the memory element 210 is first programmed into the high resistivity, antiparallel RESET state by applying two low read current pulses separated by a high current RESET pulse in the RESET direction. The threshold voltage of the memory cell 180 has the V_{th,-/-} value. The memory element 210 is then programmed into the low resistivity, parallel SET state by applying a high current SET pulse in the SET direction. The threshold voltage of the memory cell 180 switches from V_{th,-/-} value to the V_{th,-/+} value. It is desirable to maximize the V_{th,-/+} value to enhance the write probability to the SET state. The memory cell 180 is then read by applying the two low read current pulses separated by a high current RESET pulse in the RESET direction. The threshold voltage of the memory cell 180 switches from the V_{th,-/+} value to the V_{th,+/-} value after the first read current pulse. It is desirable to minimize the V_{th,+/-} value to avoid read disturb during the sensing (i.e., reading operation). The memory cell 180 switches to the V_{th,-/-} value after the high current RESET pulse and remains in the V_{th,-/-} value after the second low current read pulse. Since the first and second read voltages sensed during the first and the second read pulses are different, the sensing operation determines that the memory element 210 was in the parallel SET state prior to the read operation.

In order to maximize the V_{th,-/+} value and to minimize the V_{th,+/-} value in a bottom pinned MTJ memory cell 180, the ΔVₜₕ₍₋₎ value should be maximized, and the ΔVₜₕ₍₊₎ value should be minimized. Therefore, the high conductivity insert (or the high conductivity electrode) 142 is located on the bottom of the OTS memory material portion 150 of the OTS selector 200 to maximize ΔVₜₕ₍₋₎ and minimize ΔVₜₕ₍₊₎.

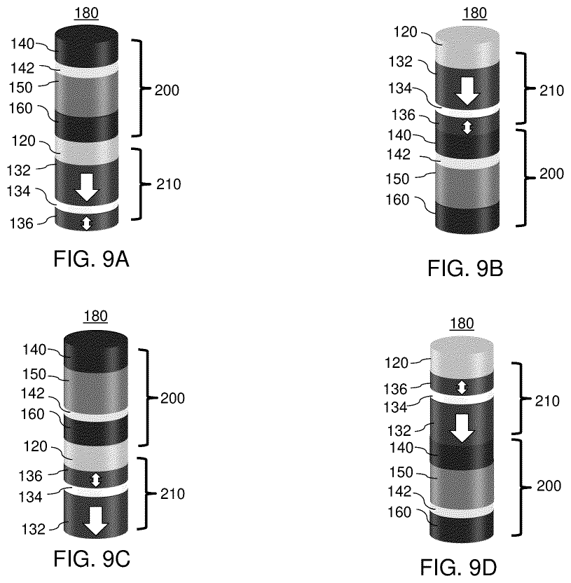

Referring to FIGS. 9A-9D, the respective memory cells 180 of FIG. 7A-7D may have a cylindrical shape having a straight sidewall. Thus, the sidewall of the OTS selector 200 may be vertically coincident with the sidewall of the MTJ memory element 210. The higher conductivity electrode of the OTS selector 200 is located on the same side of the OTS material portion 150, as the position of the reference layer 132 relative to the tunneling barrier layer 134 in the MTJ memory element 210. Thus, if the reference layer 132 is located above the tunneling barrier layer 134 in a top pinned MTJ memory element 210, then the higher conductivity electrode 142 is located on the top side of the OTS selector 200. In contrast, if the reference layer 132 is located below the tunneling barrier layer 134 in a bottom pinned MTJ memory element 210, then the higher conductivity electrode 142 is located on the bottom side of the OTS selector 200.

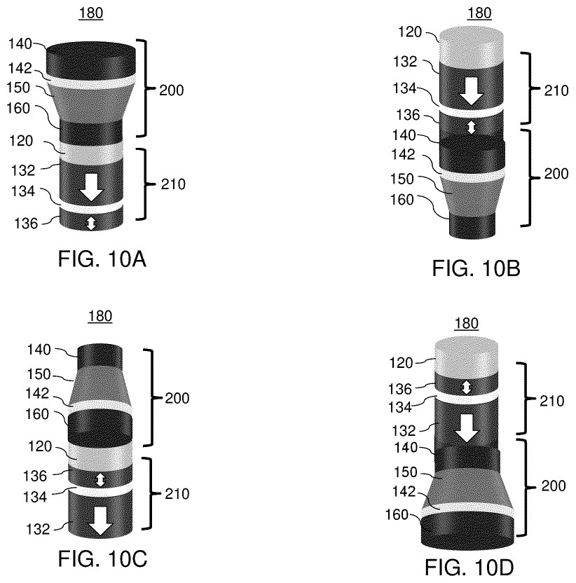

Referring to FIGS. 10A-10D, in an alternative embodiment, the respective memory cells 180 of FIG. 7A-7D may include cylindrical MTJ memory element 210 and the frustum shaped OTS selector 200 of the type illustrated in FIG. 5C. In this embodiment, the OTS selector 200 has the tapered shape, where the larger diameter electrode has a higher conductivity than the smaller diameter electrode.

In summary, a memory cell 180 of the second embodiment comprises a memory element 210 and an ovonic threshold switch (OTS) selector 200 electrically connected to the memory element 210 in series. The OTS selector 200 comprises a first electrode (140 or 160) having a first electrical conductivity; a second electrode (e.g., 142) having a second electrical conductivity which is higher than the first electrical conductivity; and an OTS material portion 150 located between and directly contacting the first electrode and the second electrode.

In various embodiments, the memory cell 180 comprises a vertical stack of the memory element 210 and the OTS selector 200. In one embodiment, the memory element 210 comprises a magnetic tunnel junction (MTJ) (132, 134, 136). The MTJ comprises a vertical stack of a ferromagnetic reference layer 132, a ferromagnetic free layer 136 and a tunnel barrier layer 134 located between the ferromagnetic reference layer and the ferromagnetic free layer. The OTS selector 200 comprises a vertical stack of the first electrode, the OTS material portion and the second electrode.

In the embodiments of FIGS. 7A, 7B, 8A, 8B, 9A, 9B, 10A and 10B, the MTJ (132, 134, 136) comprises a top pinned MTJ in which the ferromagnetic reference layer 132 is located above the ferromagnetic free layer 136. In these embodiments, the second electrode 142 of the OTS selector is located above and contacting the OTS material portion 150, and the first electrode 160 is located below and contacting the OTS material portion 150. In the embodiments of FIGS. 7A, 9A and 10A, the memory element 210 is located below the OTS selector 200. In the embodiments of FIGS. 7B, 9B and 10B, the memory element 210 is located above the OTS selector 200.

In the embodiments of FIGS. 7C, 7D, 8C, 8D, 9C, 9D, 10C and 10D, the MTJ (132, 134, 136) comprises a bottom pinned MTJ in which the ferromagnetic reference layer 132 is located below the ferromagnetic free layer 136. In these embodiments, the second electrode 142 of the OTS selector 200 is located below and contacting the OTS material portion 150, and the first electrode 140 is located above and contacting the OTS material portion 150. In the embodiments of FIGS. 7C, 9C and 10C, the memory element 210 is located below the OTS selector 200. In the embodiments of FIGS. 7D, 9D and 10D, the memory element 210 is located above the OTS selector 200.

In the embodiments of FIGS. 9A-9D, the OTS selector 200 has a cylindrical shape in which a sidewall of the OTS material portion is vertically coincident with a respective sidewall of the first electrode and is vertically coincident with a respective sidewall of the second electrode.

In the embodiments of FIGS. 10A-10D, the OTS selector 200 has a tapered shape, the first electrode (140 or 160) has a first horizontal cross-sectional area; and the second electrode 142 has a second horizontal cross-sectional area which is larger than the first horizontal cross-sectional area.

A method of operating the memory cell 180 of the second embodiment includes sensing a memory state of the memory element 210 by applying at least one read current pulse to the memory cell such that the current flows from ferromagnetic reference layer 132 to the ferromagnetic free layer 136 through the tunnel barrier layer 134, and a positive read voltage is provided to a side of the memory cell 180 facing the ferromagnetic reference layer 132 (i.e., the top side for a top pinned MTJ and the bottom side for a bottom pinned MTJ).

The method also includes applying a RESET current pulse having a greater magnitude than the read current pulse to the memory cell 180 such that the current flows from ferromagnetic reference layer 132 to the ferromagnetic free layer 136 through the tunnel barrier layer 134 to program the memory element into an antiparallel RESET state; and applying a SET current pulse having a greater magnitude than the read current pulse to the memory cell 180 such that the current flows from ferromagnetic free layer 136 to the ferromagnetic reference layer 132 through the tunnel barrier layer 134, to program the memory element into an parallel SET state.

In one embodiment, the step of sensing the memory state of the memory element 210 comprises applying first and second read current pulses separated by the RESET programming pulse to the memory cell 180 such that the current flows from ferromagnetic reference layer 132 to the ferromagnetic free layer 136 through the tunnel barrier layer 134, and comparing a first voltage sensed during the first read current pulse to a second voltage sensed during the second read current pulse. If the first voltage is less than the second voltage, then the memory cell 180 was in the SET state where the MTJ memory element 210 was in the parallel state. If the first voltage equals to the second voltage, then the memory cell 180 was in the RESET state where the MTJ memory element 210 was in the antiparallel state. Thus, the method also includes determining that the MTJ memory element 210 is in the antiparallel state if the first voltage sensed during the first read current pulse is equal to the second voltage sensed during the second read current pulse; and determining that the memory element 210 is in the parallel state if the first voltage sensed during the first read current pulse is not equal to (e.g., less than) the second voltage sensed during the second read current pulse.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. An ovonic threshold switch (OTS) memory element, comprising:
a first electrode having a first electrical conductivity;
a second electrode having a second electrical conductivity which is higher than the first electrical conductivity; and
an OTS material portion located between and directly contacting the first electrode and the second electrode.

2. The OTS memory element of claim 1, wherein the first electrode comprises a carbon or carbon nitride material directly contacting the OTS material portion, and the second electrode comprises a metal, metal alloy or a conductive metal nitride material directly contacting the OTS material portion.

3. The OTS memory element of claim 1, wherein the second electrode comprises an outer portion and an insert having the second electrical conductivity which is located between the outer portion and the OTS material portion, and directly contacting the OTS material portion.

4. The OTS memory element of claim 3, wherein:
the first electrode consists essentially of carbon or carbon nitride material having the first electrical conductivity and directly contacting the OTS material portion;
the outer portion of the second electrode consists essentially of carbon or carbon nitride material; and
the insert comprises a conductive metal nitride material.

5. The OTS memory element of claim 4, wherein the insert comprises TiN, TaN, WN or MoN.

6. The OTS memory element of claim 1, wherein the OTS material portion comprises an amorphous chalcogenide material.

7. The OTS memory element of claim 1, wherein second electrical conductivity is at least two times higher than the first electrical conductivity.

8. The OTS memory element of claim 1, wherein second electrical conductivity is at least ten times higher than the first electrical conductivity.

9. The OTS memory element of claim 1, wherein the OTS memory element comprises a vertical stack of the first electrode, the OTS material portion and the second electrode.

10. The OTS memory element of claim 9, wherein the first electrode is located below the OTS material portion and the second electrode is located above the OTS material portion.

11. The OTS memory element of claim 9, wherein the first electrode is located above the OTS material portion and the second electrode is located below the OTS material portion.

12. The OTS memory element of claim 9, wherein the OTS memory element has a cylindrical shape in which a sidewall of the OTS material portion is vertically coincident with a respective sidewall of the first electrode and is vertically coincident with a respective sidewall of the second electrode.

13. The OTS memory element of claim 9, wherein the OTS memory element has a tapered shape.

14. The OTS memory element of claim 13, wherein the OTS material portion comprises a tapered sidewall having a uniform taper angle between 5 and 45 agrees relative to a vertical direction.

15. The OTS memory element of claim 13, wherein:
the first electrode has a first horizontal cross-sectional area; and
the second electrode has a second horizontal cross-sectional area which is smaller than the first horizontal cross-sectional area.

16. The OTS memory element of claim 15, wherein the first electrode is located above the OTS material portion and the second electrode is located below the OTS material portion.

17. The OTS memory element of claim 1, wherein the OTS memory element comprises a selector-only memory device.

18. An ovonic memory device comprising:
first electrically conductive lines laterally extending along a first horizontal direction and laterally spaced apart from each other along a second horizontal direction;
second electrically conductive lines vertically spaced from the first electrically conductive lines, laterally extending along the second horizontal direction, and laterally spaced apart from each other along the first horizontal direction; and
a two-dimensional array of the OTS memory elements of claim 1 located at cross points between the first electrically conductive lines and the second electrically conductive lines.

19. The ovonic memory device of claim 18, further comprising a programming and sensing circuit electrically connected to one of the first and second electrically conductive lines.

20. The ovonic memory device of claim 19, further comprising a row decoder circuit electrically connected to another one of the first and second electrically conductive lines.
